(19) United States
(12) Patent Application Publication
(10) Pub. No.: US 2005/0273679 A1
(43) Pub. Date: Dec. 8, 2005

(54) Semi-conductor component test procedure, in particular for a system with several modules, each comprising a data buffer component, as well as a test module to be used in a corresponding procedure

(75) Inventor: Thorsten Bucksch, Munchen (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munchen (DE)

(21) Appl. No.: 11/136,714

(22) Filed: May 25, 2005

(30) Foreign Application Priority Data
May 28, 2004 (DE) 10 2004 026 248.9

(51) Int. Cl. G11C 29/00; G01R 31/28

(52) U.S. Cl. 714/718

(57) ABSTRACT

The invention relates to a semi-conductor component test procedure for a system with several memory component modules, each comprising at least one memory component with a buffer connected in series before it, whereby a test module is used for testing, which test module comprises a buffer, not however a memory component corresponding with the memory components of the memory component modules. Furthermore the invention relates to a test module to be used during a corresponding procedure, in particular to a test module, which comprises a buffer, not however a memory component corresponding with the memory components of the memory component modules.

A semi-conductor component test procedure, in particular for a system with several modules, each comprising a data buffer component, as well as a test module to be used in a corresponding procedure

The invention relates to a semi-conductor component test procedure, as well as to a test module to be used in such a procedure.

Semi-conductor components, e.g. corresponding integrated (analog and/or digital) computer circuits, semi-conductor memory components, such as for instance function memory components (PLAs, PALs, etc.) and table memory components (e.g. ROMs or RAMs, particularly SRAMs and DRAMs), etc. are subjected to numerous tests during the course of the manufacturing process.

For the simultaneous manufacture of numerous (generally identical) semi-conductor components, a so-called wafer (i.e. a thin disk consisting of monocrystalline silicon) is used. The wafer is appropriately processed (e.g. subjected to numerous coating, exposure, etching, diffusion and implantation process steps, etc.), and subsequently sawn up (or e.g. scored and snapped off), so that the individual components become available.

During the manufacture of semi-conductor components (e.g. DRAMs (Dynamic Random Access Memories and/or dynamic read/write memories), particularly of DDR-DRAMs (Double Data Rate—DRAMs and/or DRAMs with double data rate)) the components (still on the wafer and incomplete) may be subjected to corresponding test procedures at one or several test stations by means of one or several test apparatuses (e.g. the so-called kerf measurements at the scoring grid) even before all the required above processing steps have been performed on the wafer (i.e. even while the semi-conductor components are still semi-complete).

After the semi-conductor components have been completed (i.e. after all the above wafer processing steps have been performed) the semi-conductor components are subjected to further test procedures at one or several (further) test stations; for instance the components—still present on the wafer and completed—may be tested with the help of corresponding (further) test apparatuses (“disk tests”).

In corresponding fashion several further tests may be performed (at further corresponding test stations and by using corresponding further test equipment) e.g. after the semi-conductor components have been installed in corresponding semi-conductor-component housings, and/or e.g. after the semi-conductor component housings (together with the semi-conductor components installed in them) have been installed in corresponding electronic modules (so-called “module tests”).

During testing (e.g. during the above disk tests, module tests, etc.), the semi-conductor components may be subjected to so-called “DC tests” and/or e.g. to so-called “AC tests” as test procedures.

During a DC test for instance a voltage (or current) at a specific—in particular a constant—level may be applied to corresponding connections of a semi-conductor component to be tested, whereafter the level of the—resulting—currents (and/or voltages) are measured—in particular tested to see whether these currents (and/or voltages) fall within predetermined required critical values.

During an AC test in contrast, voltages (or currents) at varying levels can for instance be applied to the corresponding connections of a semi-conductor component, particularly corresponding test sample signals, with the help of which appropriate function tests may be performed on the semi-conductor component in question.

With the aid of above test procedures defective semi-conductor components and/or modules may be identified and then sorted out (or else partially repaired as well), and/or the procedure parameters—applied during the manufacture of the components in each case—may be appropriately modified and/or optimized in accordance with the test results achieved etc., etc.

For numerous applications—e.g. in server or work station computers, etc., etc.—memory modules with data buffer components (so-called buffers) connected in series, e.g. so-called “buffered DIMMs”, may be used.

Memory modules of this nature generally contain one or several semi-conductor memory components, particularly DRAMs, and—connected in series before the semi-conductor memory components—one or several data buffer components (which may for instance be installed on the same card as the DRAMs).

The memory modules are connected—particularly when a corresponding memory controller has been connected in series (e.g. arranged externally to the memory module in question)—with one or several micro-processors of a particular server or work station computer, etc.

In partially buffered memory modules, the address and control signals—e.g. emitted by the memory controller, or by the processor in question—may be (briefly) retained by corresponding data buffer components and then relayed—in chronologically coordinated, or where appropriate, in multiplexed or de-multiplexed fashion—to the memory components, e.g. DRAMs.

In contrast, the (useful) data signals—emitted by the memory controller and/or by each processor—may be directly—i.e. without being buffered by a corresponding data buffer component (buffer)—relayed to the memory component (and—conversely—the (useful) data signals directly emitted by the memory components may—without a corresponding data buffer component (buffer) being connected in series—relayed to the memory controller and/or to each processor).

With “fully buffered” memory modules in contrast, the address and control signals exchanged between the memory component and each processor and/or the memory controller, and also the corresponding (useful) data signals may first be retained by corresponding data buffer components, and only afterwards relayed to the memory component and/or the memory controller or each processor.

In particular with memory modules for servers or work stations the exchange of (useful) data and/or address and/or control signals between the memory controller and/or processor, and the respective data buffer component may take place via a high-speed multiplex data connection allowing relatively high data rates (e.g. up to 4.8 Gbit/s), whereby the data emitted by the respective transmitter (e.g. by the processor and/or controller (or the data buffer component)) is always correspondingly multiplexed and the data received by the respective receiver (e.g. by the data buffer component (or by the processor and/or controller)) is always correspondingly de-multiplexed.

The exchanging of (useful) data and/or address and/or control signals between the respective data buffer component and the memory components provided on the respective module may then take place at a correspondingly lower data rate than with the above high-speed data connection provided between the controller and/or processor and corresponding data buffer component.

If the above—fully or partially buffered—memory module is subjected to a corresponding module test, in particular to a module function test, the problem arises that conventional test apparatuses—used to communicate between the controller and/or processor and the corresponding data buffer component—do not support relatively high data rates.

The invention is aimed at making available a novel semi-conductor component test procedure, in particular one relatively less cumbersome, as well as a novel test module to be used in a corresponding procedure.

It achieves these and other aims by means of the subject matters of claims 1 and 7.

Advantageous further developments of the invention are listed in the subsidiary claims.

In terms of one aspect of the invention, a semi-conductor component test procedure for a system with several memory component modules, each comprising at least one memory component with a buffer connected in series before it, is made available, whereby a test module is used for testing, which module comprises a buffer but not a memory component corresponding with the memory components of the memory component module.

Advantageously, the signals emitted by the buffer of the test module are relayed to a test apparatus.

Preferably the buffer of the test module may be similarly or identically constructed to a buffer of one of the memory component modules (particularly in such a way that the test module buffer—in comparison with the memory component module buffers—does not make any separate, additional test functions available).

Thanks to the relatively simple construction of the test module buffer, these may be manufactured relatively cheaply, relatively less susceptible to failure and with only a relatively small chip area.

Below, the invention is more closely described by means of several embodiment examples and the attached illustration. In the illustration:

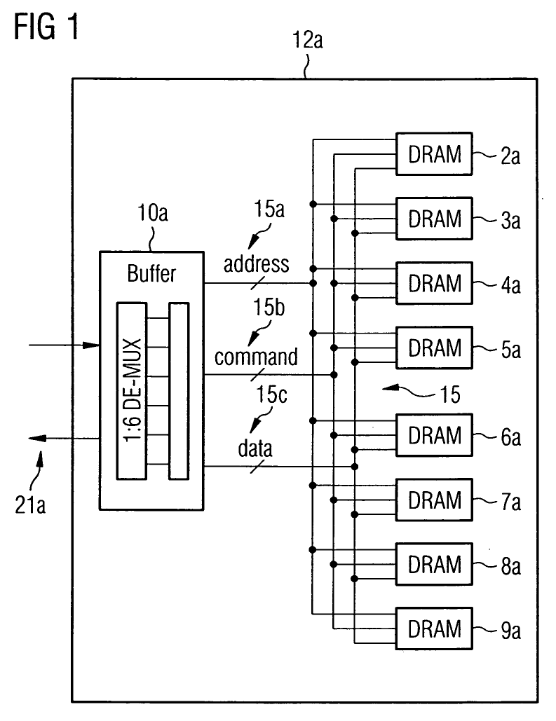

FIG. 1 shows a schematic representation of a fully buffered memory module with corresponding memory components, and a data buffer component;

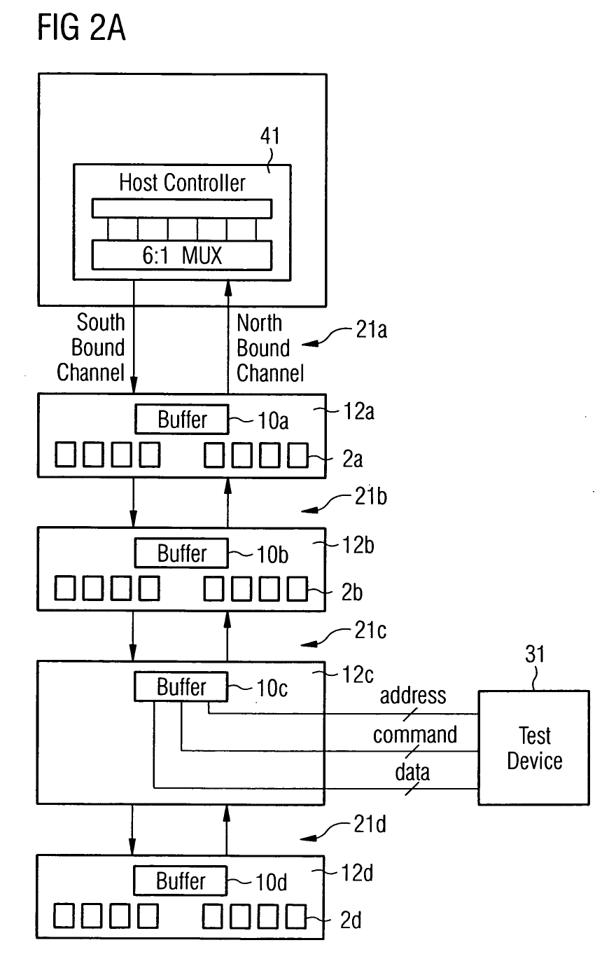

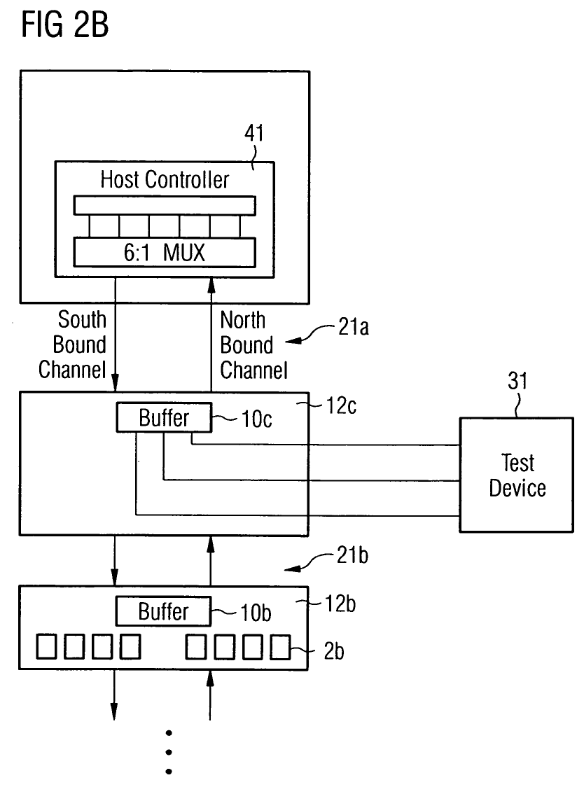

FIG. 2a shows a schematic representation of several memory modules connected with a controller and/or with a processor, a special test module—provided with data buffer component but without memory components—and a test apparatus connected with it, to illustrate a semi-conductor component test procedure in terms of a first embodiment example of the invention;

FIG. 2b shows a schematic representation of several memory modules connected with a controller and/or with a processor, a special test module—provided with data buffer component but without memory components—and a test apparatus connected to it, to illustrate a semi-conductor component test procedure in terms of a second embodiment example of the invention; and

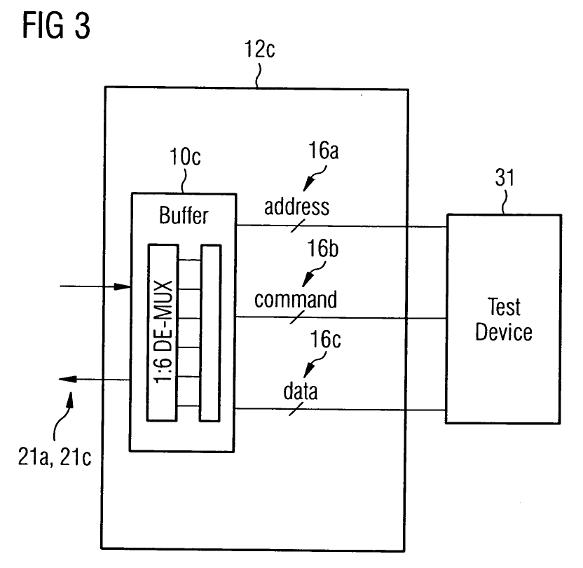

FIG. 3 shows a schematic representation of the test module shown in FIGS. 2a and 2b.

In FIG. 1 a schematic representation of a fully buffered memory module 12a is shown (here: a “fully buffered DIMM” and/or FB-DIMM 12a).

This contains numerous memory components 2a, 3a, 4a, 5a, 6a, 7a, 8a, 9a and—connected in series before the memory components 2a, 3a, 4a, 5a, 6a, 7a, 8a, 9a—a data buffer component (“buffer”) 10a.

The memory components 2a, 3a, 4a, 5a, 6a, 7a, 8a, 9a may for instance be function storage components or table memory components (e.g. ROMs or RAMs), particularly SRAMs or RAMs, particularly DDR (Double Data Rate) DRAMs.

As is apparent from FIG. 1, the memory components 2a, 3a, 4a, 5a, 6a, 7a, 8a, 9a have been installed on the same card as the buffer 10a.

As is more closely described below, the memory module 12a and/or the memory module card (and—as shown in FIGS. 2a and 2b—numerous further memory modules 12b, 12d and/or memory module cards) may be electrically connected with one or several micro-processors with an interconnected corresponding memory controller 41 (e.g. one installed externally to the memory modules 12a, 12b, 12d and/or the corresponding cards), in particular connected with one or more micro-processors of a server or work station computer—provided on one or more further cards, in particular a motherboard—(or with any other micro-processor, e.g. of a PC, laptop, etc.).

The memory module 12a shown in FIG. 1 (and/or the memory module card)—and also the memory modules 12a, 12b, 12d and/or memory module cards shown in FIGS. 2a and 2b—may in each case be constructed as plug-in cards and e.g. plugged into corresponding sockets in the above motherboard.

As is apparent from FIG. 1 and more closely illustrated below, corresponding (useful) data, control and address signals e.g. those deriving from the memory controller and/or the respective processor, and e.g. relayed via a corresponding high-speed multiplex data bus 21a (in particular a corresponding first channel (“south-bound channel”)) may be—briefly—buffered in the buffer 10a of the memory module 12a, before being relayed—in chronologically coordinated and de-multiplexed fashion—to the memory components 2a, 3a, 4a, 5a, 6a, 7a, 8a, 9a provided on the memory module 21a (e.g. via corresponding data, control or address buses 15a, 15b, 15c (connected with a central bus 15)).

Correspondingly inverted, the corresponding (useful) data, control and address signals emitted by the memory components 2a, 3a, 4a, 5a, 6a, 7a, 8a, 9a to the above central bus 15 (in particular to the corresponding data, control or address bus 15a, 15b, 15c) may be—briefly—buffered before being relayed—in a chronologically coordinated and multiplexed fashion—to the memory controller and/or respective processor (e.g.—also—via the above high-speed multiplex data bus 21a, in particular via a corresponding further channel (i.e. a return channel (here: a “north-bound channel”))).

The exchanging of the (useful) data and/or address and/or control signals between the memory controller 41 and/or processor and the buffer 10a via the above high-speed multiplex data bus 21a may take place at a relatively high data rate (e.g. at between 2 and 10 Gbit/s, in particular e.g. at up to 4.8 Gbit/s), whereby the data emitted by the respective transmitter (e.g. by the processor and/or controller 41 (or by the buffer 10a)) may be correspondingly multiplexed in each case (e.g. subjected to a 6:1 multiplexing), while the data received from the respective receiver (e.g. from the buffer 10a (or from the processor and/or controller 41)) may be correspondingly de-multiplexed in each case (e.g. subjected to a 1:6 de-multiplexing).

The exchanging of the (useful) data and/or address and/or control signals between the buffer 10a and the memory components 2a, 3a, 4a, 5a, 6a, 7a, 8a, 9a provided on the memory module 12a (via the above central bus 15 and/or the corresponding data, control or address buses 15a, 15b, 15c), may take place at a data rate relatively lower than with the above high-speed data connection provided between the controller 41 and/or processor and the buffer 10a (e.g. simply at between 0.1 and 2 Gbit/s, etc.).

As is apparent from FIGS. 2a and 2b, the exchanging of (useful) data and/or address and/or control signals between the individual memory modules (e.g. between the memory module 12a and the memory module 12b, etc.)—and/or more accurately: between the respective buffers of the memory module (e.g. between buffer 10a of the memory module 12a, and buffer 10b of the memory module 12b)—takes place in correspondingly similar fashion to that taking place between the memory controller 41 and/or processor and buffer 10a of the memory module 10a, via corresponding high-speed multiplex data buses 21b, 21c, 21d (and/or more accurately: in each case via a corresponding return channel).

The exchanging of (useful) data and/or address and/or control signals between the various memory module buffers (e.g. between buffer 10a of the memory module 12a and buffer 10b of memory module 12b, etc.) may—corresponding with the description for bus 21a above—take place at a relatively high data rate (e.g. at between 2 and 10 Gbit/s, in particular e.g. at up to 4.8 Gbit/s), whereby the data emitted by the respective transmitter (i.e. by the buffer emitting the respective data) may in each case be correspondingly multiplexed (e.g. subjected to 6:1 multiplexing), and the data received (i.e. by the buffer receiving the respective data) may in each case be correspondingly de-multiplexed (e.g. subjected to 1:6 de-multiplexing) by the respective receiver.

The various memory modules 21a, 21b, 21d (and/or the corresponding buffer 10a, 10b, 10d provided there) operate according to the “daisy chain” principle.

The signals emitted—via bus 21a—by the memory controller 41 and/or the corresponding processor to the first link of the “daisy chain” (here e.g.: the memory module 12a) contain data identifying the memory module (memory modules 12a, 12b, 12d, etc.) which is being addressed in each case.

Buffer 10a of the memory module 12a (i.e. of the first link of the “daisy chain”) relays the data, address and control signals (where required, after being appropriately re-amplified) received from the memory controller 41 and/or the corresponding processor—via bus 21a—to the second link of the “daisy chain” via bus 21b (here: to buffer 10b of the memory module 12b) from where (after appropriate reamplification if needed) the data, address and control signals are relayed to the third link of the “daisy chain” etc., etc.)

Each buffer 10a, 10b knows its position in the chain. Which of the memory modules 12a, 12b is being addressed at any time may be determined in the respective buffer 10a, 10b, e.g. by comparing the received memory module identification data stored there with the identification data (“ID number”) individually identifying the respective buffer.

For chronological reasons the relaying of data, address and control signals between the individual memory modules (and/or buffers) takes place regardless of which of the memory modules 12a, 12b, etc. has actually been addressed in each case (i.e. regardless of the memory module identification data contained in the respective signals).

However, the corresponding data, address and control signals are relayed—in chronologically coordinated and de-multiplexed fashion—only by that buffer 10a, 10b of that memory module 12a, 12b which is actually being addressed in each case (and which has been correspondingly identified by means of the identification data) to the memory components on the memory module 12a, 12b being addressed in each case (not however by the buffers of the remaining—non-addressed—memory modules).

Correspondingly inverted to that described above, the data, address and control signals sent in the reverse direction (“north-bound”) via a corresponding bus 21d also are in each case relayed by the receiving buffer (if needed, after being appropriately re-amplified) to the respective preceding buffer (and/or memory controller) in the daisy chain (from where the data, address and control signals (if needed, after being appropriately re-amplified) are relayed to the buffers located further down the daisy chain, etc., etc.).

During “normal operation” (conventional) memory modules 12a, 12b, constructed and operating as described above (containing a buffer 10a and corresponding memory components 2a, 3a, 4a, 5a, 6a, 7a, 8a, 9a) are plugged into all the sockets of the motherboard.

During “test operation”—as shown in FIGS. 2a and 2b—a conventional memory module (represented in FIG. 1) is replaced by a special test module 12c (represented in FIG. 3), i.e. a test module 12c (represented in FIG. 3) is inserted into a socket 12a, 12b, 12c provided during “normal operation” for a conventional memory module containing a buffer and corresponding memory components.

As is for instance apparent from FIG. 2b, as an alternative to the arrangement for instance shown in FIG. 2a, the test module 12c may be inserted into any other memory module socket, which differs from that shown in FIG. 2a, and/or may replace any other memory module than that shown in FIG. 2a (in particular e.g.—as shown in FIG. 2b—the “first” memory module 12a of the daisy chain).

As is apparent from FIG. 3, the test module 12c—used during test operation—is essentially identically constructed and operates essentially identically to the—conventional—memory module shown in FIG. 1, except that a buffer 10c—constructed and operating correspondingly identically or similarly to a conventional buffer 10a shown in FIG. 1—has been provided on test module 12c, not however any memory components (corresponding with the memory components 2a, 3a, 4a, 5a, 6a, 7a, 8a, 9a shown in FIG. 1).

Buffer 10c of the test module 12c (in identical fashion to the buffers 10a, 10b of the conventional memory module) relays the data, address and control signals received from the preceding (or succeeding) buffer (and/or memory controller) in the daisy chain via the respective bus 21a, 21c (if needed, after corresponding re-amplification) via the corresponding bus 21a, 21b, 21c to the succeeding (or preceding) link of the “daisy chain” (and/or the corresponding buffer and/or memory controller).

In a first version of the invention, an ID number—individually identifying buffer 10c—is stored on buffer 10c of the test module 12c (similar to buffer 10a of the conventional memory module 12a), in particular the ID number of that buffer of that memory module, which is replaced by the test module 12c, or e.g. of a buffer of a remaining memory module as shown in FIGS. 2a and 2b, which has not been replaced (e.g. the identical ID number as for buffer 10a, or buffer 10b, etc.).

The buffer 10c then—correspondingly identically to the other buffers—decodes and/or deserialises only those signals destined for the corresponding module (here: the test module 12c, and/or—actually—a memory module replaced by it, and/or one of the remaining memory modules).

With the aid of buffer 10c the corresponding (useful) data, control and address signals e.g. deriving from the memory controller 41, and/or from the respective processor, e.g. relayed via bus 21a and destined for module 12c, are—briefly—retained, and emitted—in a chronologically coordinated and de-multiplexed fashion—to corresponding data, control or address buses 16a, 16b, 16c (FIG. 3), so that the corresponding signals could then be received and evaluated by the memory components corresponding with the memory components 2a, 3a, 4a, 5a, 6a, 7a, 8a, 9a shown in FIG. 1.

Instead, the signals (corresponding with the signals emitted by buffer 10a shown in FIG. 1) emitted at corresponding memory component lines, in particular DRAM signal lines (i.e. at the above data, control and address buses 16a, 16b, 16c) of the buffer 10c are relayed to corresponding connections—accessible to a test apparatus 31—and/or to a socket rail, and from there to the test apparatus 31 shown in FIGS. 2a, 2b and 3.

With the aid of the test apparatus 31 corresponding conventional test procedures may then be performed, in particular corresponding function tests and/or AC tests for testing the functionality, e.g. of the buffer(s) 10a, 10b, and/or of the memory controller 41, and/or of the memory components—provided on the remaining modules 12a, 12b—(e.g., by having corresponding test sample signals (of which the emission may be induced by the test apparatus 31) which are emitted by a buffer 10a and/or the memory controller/processor and received by buffer 10c correspondingly evaluated).

In a second version of the invention the buffer 10c—in contrast to the remaining buffers 10a, 10b—decodes and/or deserialises not only the signals destined for the corresponding module (here: the test module 12c, and/or—actually—a module replaced by it, and/or of the remaining memory modules) but all signals received by test module 12c (e.g. via the buses 21c and/or 21d) signals.

With the aid of buffers 10c, the corresponding (useful) data, control and address signals, e.g. deriving from the memory controller 41 and/or from the processor in question—not just destined for the module 12c, but if needed also for another module (e.g. the memory module 12d, etc.) are—briefly—retained and then emitted—in a chronologically coordinated, and de-multiplexed fashion—to the above data, control or address buses 16a, 16b, 16c (FIG. 3), so that the corresponding signals may then be correspondingly evaluated by the above test apparatus 31.

As is apparent from FIG. 3, no further data and/or signals, in particular no corresponding test reports, test control bits etc. containing data and/or signals are made available by buffer 10c to the test apparatus 31, apart from the above (useful) data, control and address signals, which could also be evaluated by corresponding memory components (not being present).

The buffer 10c may then be constructed relatively simply and economically and taking up a relatively small chip area.

In an advantageous embodiment of the invention, correspondingly lower data rates may—due to the test apparatus 31—be used during test operation on the above high-speed multiplex data buses 21a, 21b, 21c, 21d and/or the buses 15a, 15b, 15c, 16a, 16b, 16c connecting the buffers 10a, 10b, 10c with the memory components and/or the test apparatus 31, than during normal operation.

In order to perform the tests, the test apparatus 31 may in each case distinguish between the “south-bound channel” and the “north bound channel”, i.e. separate, different tests may be—electively—performed for both channels.

1. A semi-conductor component test procedure for a system with several memory component modules (12a, 12b), each comprising at least one memory component (2a, 2b) with a buffer (10a, 10b) connected in series before it, whereby a test module (12c) comprising a buffer (10c), not however a memory component (2a, 2b) corresponding with the memory components (2a, 2b) of the memory component modules (12a, 12b), is used for testing.

2. A procedure according to claim 1, whereby the buffer (10c) of the test module (12c) is identically constructed to a buffer (10a) of one of the memory component modules (12a, 12b).

3. A procedure according to claim 1, whereby signals emitted by the buffer (10c) of the test module (12c) are relayed to a test apparatus (31).

4. A procedure according to claim 3, whereby the signals relayed by the buffer (10c) of the test module (12c) to the test apparatus (31) could be evaluated by memory components constructed in accordance with the memory components (2a, 2b) of the memory component modules (12a, 12b).

5. A procedure according to claim 3, whereby the signals relayed by the buffer (10c) of the test module (12c) to the test apparatus (31) are only memory component useful data, memory component control data or memory component address signals.

6. A procedure according to claim 1, whereby a memory component module provided during normal operation of the system is replaced during test operation by the test module (12c).

7. A test module (12c), which is constructed and arranged in such a way that it may be used for a procedure according to claim 1.

8. A test module (12c) according to claim 7, which comprises a buffer (10c), not however a memory component (2a, 2b) corresponding with the memory components (2a, 2b) of the memory component modules (12a, 12b).

9. A procedure according to claim 1, whereby the memory component modules (12a, 12b) are fully buffered memory component modules.

10. A procedure according to claim 1, whereby the memory component modules (12a, 12b) are partially buffered memory component modules.
